(19) United States
(12) Patent Application Publication
(10) Pub. No.: US 2014/0292405 A1
(43) Pub. Date: Oct. 2, 2014

(54) AMPLIFICATION DEVICE AND AMPLIFICATION METHOD

(71) Applicant: FUJITSU LIMITED, Kawasaki-shi (JP)

(72) Inventors: Takeshi TAKANO, Yokohama (JP); Shigekazu KIMURA, Yokohama (JP); Ken TAMANOI, Yokohama (JP); Masakazu KOJIMA, Hiratsuka (JP); Toru MANIWA, Setagaya (JP); Yasuyuki OISHI, Shibuya (JP); Michiharu NAKAMURA, Yokosuka (JP); Kazuo NAGATANI, Yokohama (JP)

(73) Assignee: FUJITSU LIMITED, Kawasaki-shi (JP)

(21) Appl. No.: 14/224,977

(22) Filed: Mar. 25, 2014

(30) Foreign Application Priority Data
Mar. 28, 2013 (JP) 2013-070680

(51) Int. Cl. H03F 1/32

(52) U.S. Cl. CPC H03F 1/32
USPC 330/149

(57) ABSTRACT

An amplification device includes: an amplitude adjustment circuit configured to adjust an amplitude level of an input signal so as to keep the amplitude level within a given range; an amplifier configured to amplify the adjusted signal; and a circuitry configured to change an amplitude level of the amplified signal, based on the amplitude level of the input signal and a first distortion compensation corresponding to the amplitude level of the input signal.

### CROSS-REFERENCE TO RELATED APPLICATION

This application is based upon and claims the benefit of priority of the prior Japanese Patent Application No. 2013-070680 filed on Mar. 28, 2013, the entire contents of which are incorporated herein by reference.

### FIELD

The embodiments discussed herein are related to an amplification device and an amplification method.

### BACKGROUND

In the related art, an amplifier is used in various electronic devices. It is known that the efficiency of the amplifier is the highest in an output saturation state (that is, a nonlinear state). Therefore, in the related art, a technology has been proposed in which the amplitude of a signal that carries information is kept at a certain level and the signal is amplified with high efficiency, and thereafter amplitude information is superimposed on the amplified signal.

In addition, in the related art, a technology has been proposed in which nonlinear distortion that is included in a signal that is amplified in an amplifier having less linearity is compensated for. In such distortion compensation, at the input of the amplifier, the input signal of the amplifier is multiplied by the reverse phase of the nonlinear distortion. As a result, the nonlinear distortion that is included in the amplified signal may be reduced.

Japanese Laid-open Patent Publication No. 2012-147385 is an example of the related art.

### SUMMARY

According to an aspect of the invention, an amplification device includes: an amplitude adjustment circuit configured to adjust an amplitude level of an input signal so as to keep the amplitude level within a given range; an amplifier configured to amplify the adjusted signal; and a circuitry configured to change an amplitude level of the amplified signal, based on the amplitude level of the input signal and a first distortion compensation corresponding to the amplitude level of the input signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example of an amplification device according to a first embodiment;

FIG. 2 is a diagram illustrating an example of a second look-up table;

FIG. 3 is a diagram illustrating an example of a first look-up table;

FIG. 4 is a flowchart illustrating an example of a processing operation of the amplification device;

FIG. 5 is a schematic diagram illustrating an example of a signal that is input to an amplifier in a case of a high level mode;

FIG. 6 is a schematic diagram illustrating an example of a signal that is input to the amplifier in a case of a low level mode;

FIG. 7 is a diagram illustrating a first configuration example of a load variable section;

FIG. 8 is a diagram illustrating a second configuration example of the load variable section;

FIG. 9 is a block diagram illustrating an example of an amplification device according to a second embodiment; and

FIG. 10 is a diagram illustrating a hardware configuration example of an amplification device.

### DESCRIPTION OF EMBODIMENTS

The embodiments of the amplification device and the amplification method discussed herein are described below in detail with reference to accompanying drawings. The amplification device and the amplification method discussed herein are not limited to the embodiments. In addition, the same reference numerals are assigned to configurations having the similar function in the embodiment, and the duplicated description is omitted herein.

While inventing the present embodiments, observations were made regarding a related art. Such observations include the following, for example.

In an amplifier of related art, when the technology is used in which the amplitude of the input signal of the amplifier is kept unchanged in order to operate the amplifier with high efficiency, it is difficult to perform distortion compensation for the amplitude component at the input of the amplifier. This is because, in the technology, it is assumed that the amplitude of the input signal of the amplifier is kept at a certain level.

Therefore, the embodiments disclosed herein may provide, for example, an amplification device and an amplification method in which amplification is performed with high efficiency, and an amplification device and an amplification method in which distortion compensation is performed.

### First Embodiment p [Configuration Example of an Amplification Device]

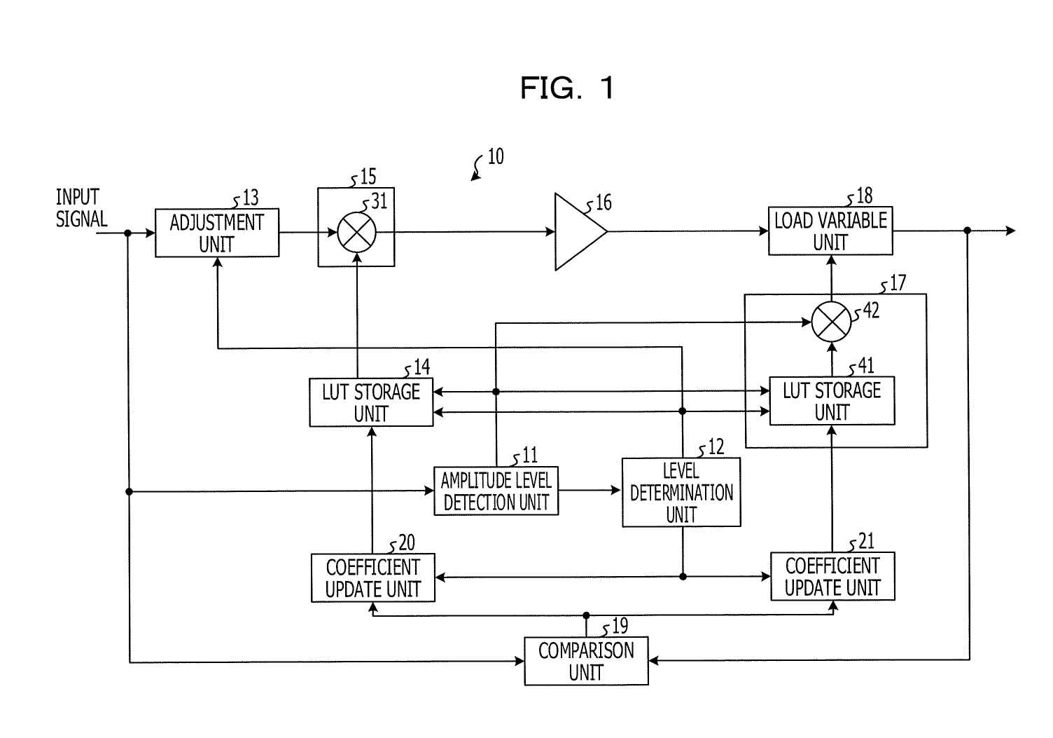

FIG. 1 is a block diagram illustrating an example of an amplification device according to a first embodiment. In FIG. 1, an amplification device 10 includes an amplitude level detection section 11, a level determination section 12, an adjustment section 13, a look-up table (LUT) storage section 14, a distortion compensation section 15, an amplifier 16, a control signal output section 17, a load variable section 18, a comparison section 19, and coefficient update sections 20 and 21.

The amplitude level detection section 11 detects the amplitude (that is, electric power) of a signal that is input to the amplification device 10. That is, the amplitude level detection section 11 extracts, for example, an envelope of the input signal. In addition, the amplitude level detection section 11 outputs the detected amplitude value to the level determination section 12, the LUT storage section 14, and the control signal output section 17. Here, the input signal includes an amplitude component and a phase component. In addition, for example, when the amplification device 10 is applied to a transmission device, the input signal is a transmission signal, and includes an I component and a Q component. In this case, the amplitude component and the phase component of the input signal vary depending on transmission data.

The level determination section 12 determines an amplitude level based on the amplitude value that is detected in the amplitude level detection section 11. For example, the level determination section 12 compares the amplitude value that is received from the amplitude level detection section 11 with a level determination threshold that is set beforehand, and determines whether the detected amplitude value is in a high level or a low level, based on the sizes of the amplitude value and the level determination threshold. For example, the level determination section 12 determines that the detected amplitude value is in the high level when the detected amplitude value is the level determination threshold or higher, and determines that the detected amplitude value is in the low level when the detected amplitude value is lower than the level determination threshold. Here, the amplification device 10 operates in a high level mode when the level determination section 12 determines that the detected amplitude value is in the high level, and operates in a low level mode when the level determination section 12 determines that the detected amplitude value is in the low level.

In addition, the level determination section 12 outputs information on the determined level (hereinafter, may be simply referred to as “level information”) to the adjustment section 13, the LUT storage section 14, and the control signal output section 17. Here, the level information indicates whether the level is the high level or the low level, and is also information on the mode (hereinafter, may be simply referred to as “mode information”).

When the level information that is received from the level determination section 12 indicates that the level is the high level, the adjustment section 13 adjusts the amplitude level of the input signal so as to keep the amplitude level within a certain range, and outputs the signal after the level adjustment to the distortion compensation section 15. As a result, the level of the amplitude of the signal that is input to the amplifier 16 is kept at a certain level, and the signal becomes a signal on which the phase information is merely superimposed. In addition, when the level information that is received from the level determination section 12 indicates the level is the low level, the adjustment section 13 outputs the input signal to the distortion compensation section 15 without adjusting the amplitude level. As a result, the signal that is input to the amplifier 16 becomes a signal on which both of the amplitude information and the phase information are superimposed.

The LUT storage section 14 outputs a second distortion compensation coefficient that corresponds to the amplitude value that is detected in the amplitude level detection section 11, to the distortion compensation section 15. For example, the LUT storage section 14 stores a second look-up table in which a plurality of address values are respectively associated with second distortion compensation coefficients that correspond to the address values. Each of the address values corresponds to a candidate of the amplitude value. In addition, the LUT storage section 14 outputs the second distortion compensation coefficient that is associated with the detected amplitude value (that is, an address value) to the distortion compensation section 15. The second distortion compensation coefficient includes an amplitude component coefficient and a phase component coefficient.

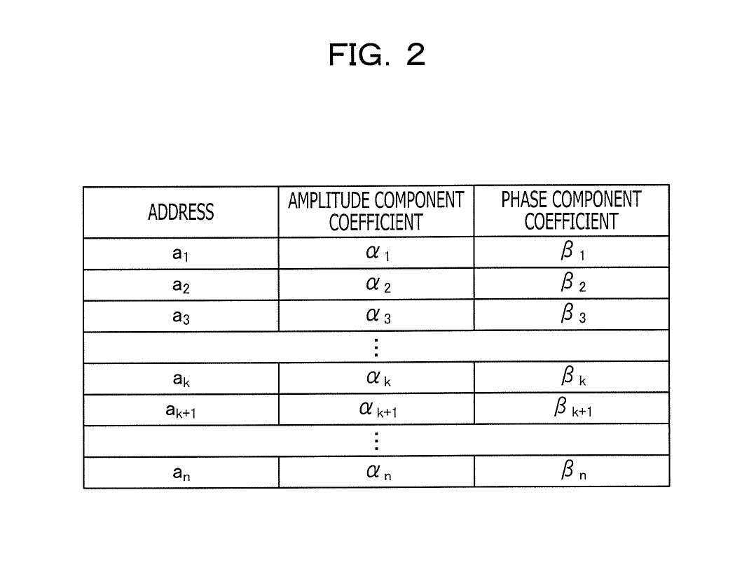

FIG. 2 is a diagram illustrating an example of the second look-up table. As illustrated in FIG. 2, in the second look-up table, a pair of an amplitude component coefficient “αₙ” and a phase component coefficient “βₙ” are associated with an address “aₙ”. In addition, an address of “aₖ” or larger corresponds to the above-described high level, an address of smaller than “aₖ” corresponds to the above-described low level. Here, “aₖ” corresponds to the above-described level determination threshold. In addition, a value of the amplitude component coefficient becomes a value that corresponds to the address in the low level range. That is, for example, as an address number becomes large, a value of the corresponding amplitude component coefficient also increases. In addition, a value of the amplitude component coefficient is a value within a certain range in the high level range regardless of an address. That is, for example, the value of the corresponding amplitude component coefficient is kept unchanged regardless of an address. Here, when the amplitude component coefficient is kept unchanged in the high level range, distortion compensation for the amplitude component is not performed in the high level range. On the other hand, a value of the phase component coefficient becomes a value that corresponds to the address regardless of whether the range is a low level range or a high level range.

In addition, the LUT storage section 14 updates, using an update coefficient that is received from the coefficient update section 20, the second distortion compensation coefficient (that is, the amplitude component coefficient and the phase component coefficient) that has been used to calculate the update coefficient and that correspond to an amplitude value (that is, an address) of a transmission signal at focused timing.

The distortion compensation section 15 performs distortion compensation for the signal that is output from the adjustment section 13 using the second distortion compensation coefficient that is received from the LUT storage section 14. Here, as described above, the value of the amplitude component coefficient that is received from the LUT storage section 14 is kept unchanged in the high level mode, so that the distortion compensation section 15 does not perform distortion compensation for the amplitude component of the input signal and merely perform distortion compensation for the phase component. In addition, the distortion compensation section 15 performs distortion compensation for both of the amplitude component and the phase component in the low level mode.

For example, the distortion compensation section 15 includes a multiplier 31. The multiplier 31 multiplies the signal that is output from the adjustment section 13 by the second distortion compensation coefficient that is output from the LUT storage section 14, and outputs the obtained signal to the amplifier 16.

The amplifier 16 amplifies the signal that is output from the distortion compensation section 15, and outputs the amplified signal to the load variable section 18. Here, the above-described high level range corresponds to a nonlinear region of the amplifier 16. In addition, the amplitude (that is, electric power) of the signal that is adjusted in the adjustment section 13 corresponds to the nonlinear region of the amplifier 16.

The control signal output section 17 generates a control signal by correcting the amplitude value that is detected in the amplitude level detection section 11, using the first distortion compensation coefficient that corresponds to the amplitude value that is detected in the amplitude level detection section 11, and the control signal output section 17 outputs the generated control signal to the load variable section 18. That is, the value of the control signal is a value also in consideration of distortion compensation. That is, the control signal output section 17 functions as an amplitude value output section that corrects the amplitude value that is detected in the amplitude level detection section 11, using the first distortion compensation coefficient that corresponds to the amplitude value that is detected in the amplitude level detection section 11, and that performs output of the corrected amplitude value.

For example, the control signal output section 17 includes a LUT storage section 41 and a multiplier 42.

The LUT storage section 41 outputs the first distortion compensation coefficient that corresponds to the amplitude value that is detected in the amplitude level detection section 11, to the distortion compensation section 15. For example, the LUT storage section 41 stores the first look-up table in which a plurality of address values are respectively associated with first distortion compensation coefficients that correspond to the address values. Each address value corresponds to a candidate of the amplitude value. In addition, the LUT storage section 41 outputs the first distortion compensation coefficient that is associated with the detected amplitude value (that is, an address value) to the multiplier 42. The first distortion compensation coefficient does not include a phase component coefficient but includes an amplitude component coefficient, which is different from the above-described second distortion compensation coefficient.

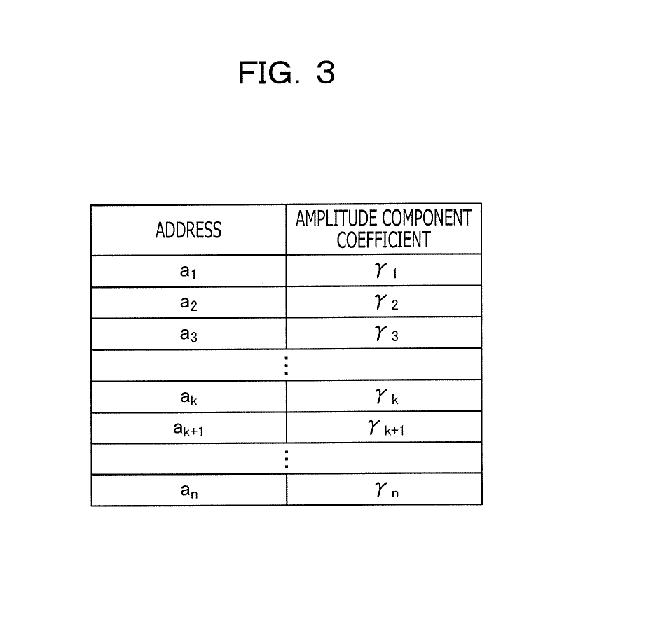

FIG. 3 is a diagram illustrating an example of the first look-up table. As illustrated in FIG. 3, in the first look-up table, an amplitude component coefficient “γₙ” is associated with an address “aₙ”. In addition, similarly to the above-described second look-up table, an address of “aₖ” or larger corresponds to the above-described high level, and an address of smaller than “aₖ38 corresponds to the above-described low level. Here, “aₖ” corresponds to the above-described level determination threshold. In addition, the value of the amplitude component coefficient is within a certain range in the low level range regardless of an address. That is, for example, the value of the corresponding amplitude component coefficient is kept unchanged regardless of an address. On the other hand, the value of the amplitude component coefficient becomes a value that corresponds to the address in the high level range. That is, for example, as an address number becomes large, a value of the corresponding amplitude component coefficient also increases. Here, when the amplitude component coefficient is kept unchanged in the low level range, distortion compensation for the amplitude component is not performed in the low level range. As described above, distortion compensation for the amplitude component is not performed at the output of the amplifier 16 in the low level range, because distortion compensation is performed in the distortion compensation section 15. In addition, in the high level range, distortion compensation for the amplitude component is not performed in the distortion compensation section 15, so that distortion compensation for the amplitude component is performed in the output of the amplifier 16. Distortion compensation for the phase component is performed in the distortion compensation section 15 regardless of whether the range is a low level range or a high level range. Thus, in the first look-up table, a phase component coefficient is not included.

In addition, the LUT storage section 41 updates, using an update coefficient that is received from the coefficient update section 21, the first distortion compensation coefficient (that is, the amplitude component coefficient) that has been used to calculate the update coefficient and that corresponds to an amplitude value (that is, an address) of a transmission signal at focused timing.

The multiplier 42 multiplies the amplitude value that is detected in the amplitude level detection section 11 by the first distortion compensation coefficient that is output from the LUT storage section 41. Such multiplication result corresponds to the control signal that is output to the load variable section 18.

The load variable section 18 changes the amplitude of the amplified signal that is output from the amplifier 16 by changing the load based on the control signal that is received from the control signal output section 17. Here, the control signal has a value based on the amplitude value that is detected in the amplitude level detection section 11, so that the amplitude information that has been superimposed on the input signal to the amplification device 10 may be superimposed on the amplified signal by changing the load in the load variable section 18 based on the control signal. In addition, the control signal has a value for which distortion compensation for the amplitude component is considered, in the high level range, so that distortion compensation for the amplitude component may be performed when the load variable section 18 changes the load based on the control signal. A configuration example of the load variable section 18 is described later.

An input signal to the amplification device 10 at each target timing is input to the comparison section 19. In addition, an output signal from the load variable section 18, which corresponds to the input signal at each target timing is input to the comparison section 19 through a feedback system. Hereinafter, the signal that is input to the comparison section 19 through the feedback system may be referred to as “a feedback signal”.

In addition, the comparison section 19 compares an input signal and a feedback signal that correspond to the same target timing. For example, the comparison section 19 subtracts the feedback signal from the input signal to obtain a difference between the input signal and the feedback signal. Further, the comparison section 19 outputs the obtained difference to the coefficient update sections 20 and 21.

The coefficient update sections 20 and 21 calculate update coefficients based on the difference that is obtained in the comparison section 19 and output the calculated update coefficients to the LUT storage sections 14 and 41, respectively. As a result, the distortion compensation coefficients are updated in the LUT storage sections 14 and 41. By repeating such update processing, finally, the value converges to an optimal distortion compensation coefficient, and distortion in the amplifier 16 is compensated for.

[Operation Example of the Amplification Device]

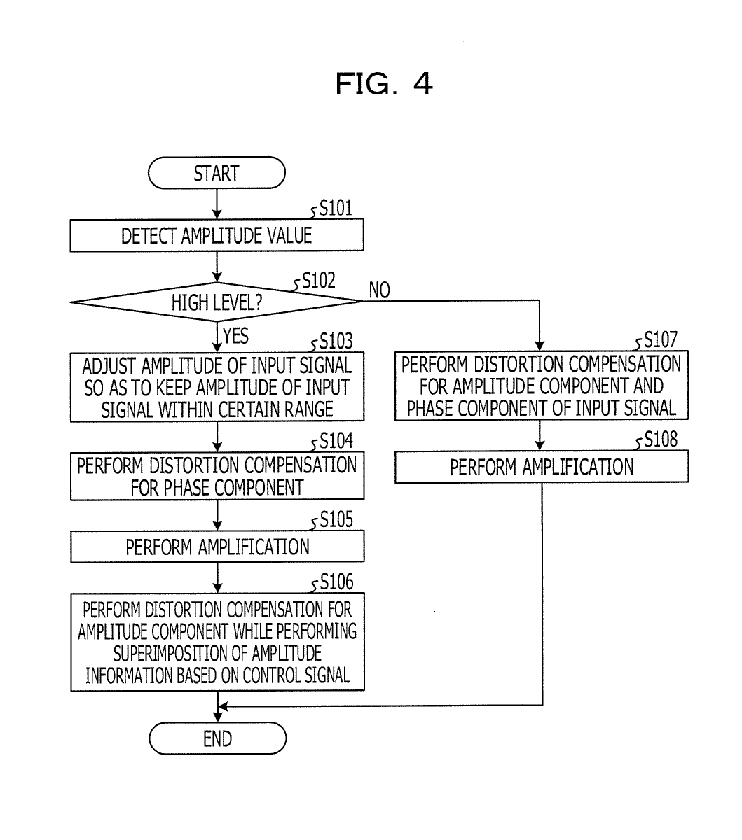

An example of a processing operation of the amplification device that includes the above-described configuration is described below. FIG. 4 is a flowchart illustrating an example of the processing operation of the amplification device. Here, in particular, distortion compensation processing in the high level mode and distortion compensation processing in the low level mode are described.

The amplitude level detection section 11 detects the amplitude value of an input signal to the amplification device 10 (Step S101).

The level determination section 12 compares the amplitude value that is received from the amplitude level detection section 11 with a level determination threshold that is set beforehand, and determines whether or not the detected amplitude value is in a high level, based on the sizes of the amplitude value and the level determination threshold (Step S102). Here, the amplification device 10 operates in the above-described high level mode when the level determination section 12 determines that the detected amplitude value is in the high level, and operates in the above-described low level mode when the level determination section 12 determines that the detected amplitude value is not in the high level, that is, the detected amplitude value is in the low level.

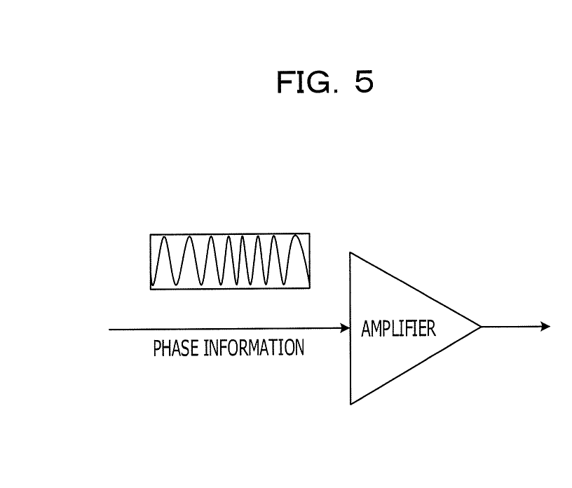

When the level determination section 12 determines that the detected amplitude value is in the high level (Yes in Step S102), the adjustment section 13 adjusts the amplitude level of the input signal so as to keep the amplitude level within a certain range (Step S103). As a result, the signal that is input to the amplifier 16 becomes a signal the amplitude level of which is kept in the certain range and on which phase information is merely superimposed. FIG. 5 is a schematic diagram illustrating an example of a signal that is input to the amplifier in the case of the high level mode. Such adjusted amplitude level corresponds to a nonlinear region of the amplifier 16. Therefore, the amplifier 16 may operate with high efficiency.

The distortion compensation section 15 does not perform distortion compensation for the amplitude component of the input signal but performs distortion compensation for the phase component of the input signal (Step S104).

The amplifier 16 amplifies the signal that is output from the distortion compensation section 15 (Step S105). In addition, the amplified signal is output to the load variable section 18.

The load variable section 18 performs distortion compensation for the amplitude component of the amplified signal while superimposing the amplitude information that has been superimposed on the input signal, on the amplified signal, based on the control signal that is received from the control signal output section 17 (Step S106).

As described above, in the high level mode, the amplifier 16 may operate with high efficiency by adjusting the amplitude level of the signal that is input to the amplifier 16 so as to keep the amplitude level at a certain level. In addition, even when the amplitude level of the signal that is input to the amplifier 16 is at a certain level, distortion compensation may be performed by executing distortion compensation processing for the amplitude component at the output of the amplifier 16.

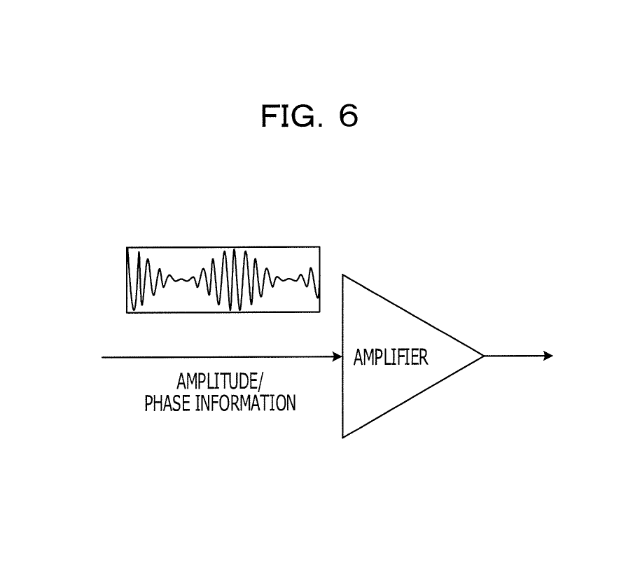

When the level determination section 12 determines that the detected amplitude value is not in the high level (No in Step S102), the adjustment section 13 outputs the input signal to the distortion compensation section 15 without adjusting the amplitude level. As a result, the signal that is input to the amplifier 16 becomes a signal on which both of the amplitude information and the phase information are superimposed. FIG. 6 is a schematic diagram illustrating an example of a signal that is input to the amplifier in the case of the low level mode.

In addition, the distortion compensation section 15 performs distortion compensation for both of the amplitude component and the phase component of the input signal (Step S107).

The amplifier 16 amplifies the signal that is output from the distortion compensation section 15 (Step S108). In addition, the amplified signal is output to the load variable section 18. Here, in the low level mode, processing of changing the amplitude of the amplified signal is not executed in the load variable section 18. This is because, in the low level mode, the adjustment processing is not executed in the adjustment section 13 and distortion compensation for the amplitude component and the phase component is performed in the distortion compensation section 15.

[Configuration Example of the Load Variable Section]

A configuration example of the load variable section 18 is described below.

### FIRST CONFIGURATION EXAMPLE

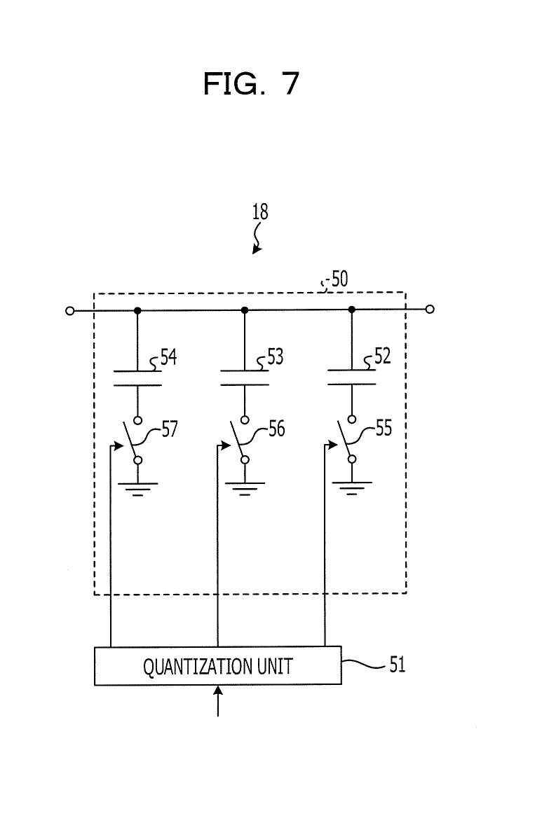

FIG. 7 is a diagram illustrating a first configuration example of the load variable section. In FIG. 7, the load variable section 18 includes a matching unit 50 and a quantization section 51.

The quantization section 51 forms a quantization bit string of quantization bit number N (here, N is a natural number of 2 or more) by quantizing the control signal that is output from the control signal output section 17.

The matching unit 50 is provided at the output of the amplifier 16 and changes the amplitude of the amplified signal that is output from the amplifier 16 by changing the load based on the quantization bit string that is formed in the quantization section 51.

For example, as illustrated in FIG. 7, the matching unit 50 includes capacitors 52, 53, and 54 that have different capacities, and switches 55, 56, and 57. That is, the matching unit 50 is a switched capacitor. One end of the capacitor 52 is connected to a main transmission line, and the other end of the capacitor 52 is grounded through the switch 55. Similarly, one end of the capacitor 53 is connected to the main transmission line, and the other end of the capacitor 53 is grounded through the switch 56. One end of the capacitor 54 is connected to the main transmission line, and the other end of the capacitor is grounded through the switch 57.

Here, the quantization bit string is constituted, for example, by 3 bits. The highest-order bit in the quantization bit string corresponds to the capacitor 52 having the largest capacity and the switch 55, and the second highest-order bit corresponds to the capacitor 53 having the second largest capacity and the switch 56. In addition, the third highest-order bit corresponds to the capacitor 54 having the third largest capacity and the switch 57. The capacity of the capacitor 52 is, for example, 4 pico-Faraday [pF], the capacity of the capacitor 53 is 2 [pF] that is ½ of the capacity of the capacitor 52, and the capacity of the capacitor 54 is 1 [pF] that is ¼ of the capacity of the capacitor 52. In addition, when the switch that corresponds to the bit the value of which is 1 in the quantization bit string is turned on, the corresponding capacitor is grounded. When the capacity value is changed depending on the quantization bit string that is a digital value as described above, the size of load impedance may be changed.

### SECOND CONFIGURATION EXAMPLE

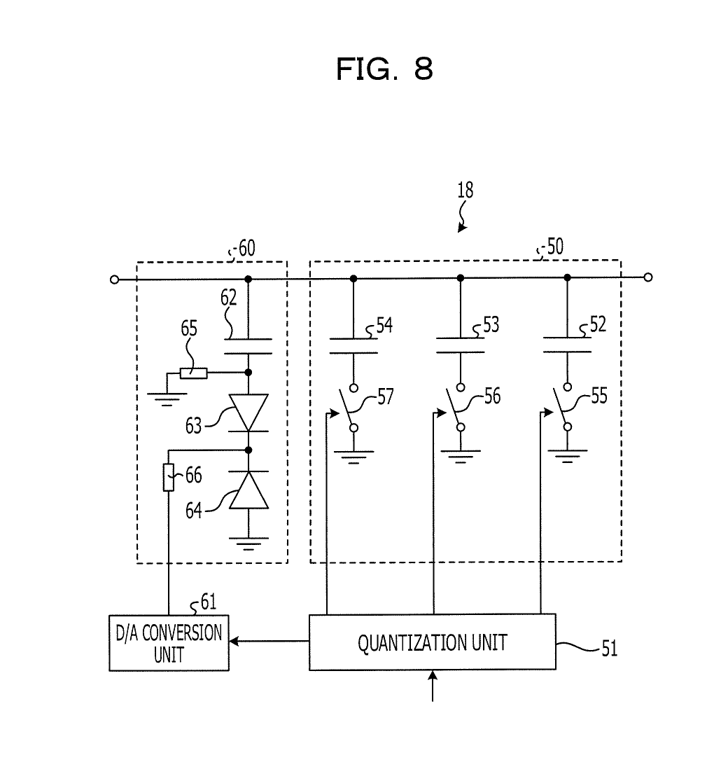

FIG. 8 is a diagram illustrating a second configuration example of the load variable section. In FIG. 8, the load variable section 18 includes a matching unit 50, a quantization section 51, a matching unit 60, and a digital/analog (D/A) conversion section 61.

The quantization section 51 forms a quantization bit string of a quantization bit number N (here, N is a natural number of 2 or more) by quantizing the control signal that is output from the control signal output section 17. The quantization bit string includes a higher-order bits group and a lower-order bit group. The higher-order bit group is output to the matching unit 50 as it is, and the lower-order bit group is converted from a digital value to an analog value in the D/A conversion section 61, and the analog value that corresponds to the lower-order bit group is output to the matching unit 60. The higher-order bit corresponds to a large step width, and the lower-order bit corresponds to a small step width.

The matching units 50 and 60 are provided at the output of the amplifier 16, and change the amplitude of the amplified signal that is output from the amplifier 16 by changing the load based on the quantization bit string that is formed in the quantization section 51.

For example, the matching unit 60 changes the capacity in accordance with an analog value that is obtained in the D/A conversion section 61. For example, as illustrated in FIG. 8, the matching unit 60 includes a pair of varactor diodes that are connected in series and in opposition to each other between the main transmission line and the ground, that is, an inverse-series varactor pair.

For example, as illustrated in FIG. 8, the matching unit 60 includes a capacitor 62, varactors 63 and 64, and resistances 65 and 66. One end of the capacitor 62 is connected to the main transmission line, and the other end of the capacitor 62 is connected to the anode of the varactor 63. The connection point between the capacitor 62 and the varactor 63 is connected to the ground through the resistance 65. The cathode of the varactor 64 is connected to the cathode of the varactor 63. The anode of the varactor 64 is grounded. The connection point between the varactor 63 and the varactor 64 is connected to the D/A conversion section 61 through the resistance 66.

Here, the capacity value is changed in accordance with an analog value (that is, an analog voltage signal) by applying the analog value to the connection point between the varactor 63 and the varactor 64. As a result, the size of the load impedance may be changed. Each of the capacities of the varactors 63 and 64 is less than the capacity of a capacitor that is included in the matching unit 60 and has the smallest capacity.

In the matching unit 60, instead of using the inverse-series varactor pair, an inverse-parallel varactor pair may be employed. That is, the matching unit 60 may include a pair of varactor diodes that are connected in parallel and in opposition to each other, that is, an inverse-parallel varactor pair between the main transmission line and the ground.

As described above, according to the first embodiment, in the case of the high level mode in the amplification device 10, the adjustment section 13 adjusts the amplitude level of the input signal so as to keep the amplitude level within a certain range. In addition, the control signal output section 17 forms a control signal by correcting the amplitude value that is detected in the amplitude level detection section 11 using the first distortion compensation coefficient that corresponds to the amplitude value that is detected in the amplitude level detection section 11. In addition, the load variable section 18 changes the amplitude of the amplified signal by changing the load based on the control signal that is formed in the control signal output section 17.

In such configuration of the amplification device 10, amplification may be performed with high efficiency, and distortion compensation for the amplitude component of the input signal may be performed.

### Second Embodiment

In a second embodiment, the load variable section is provided at the input of the amplifier as well.

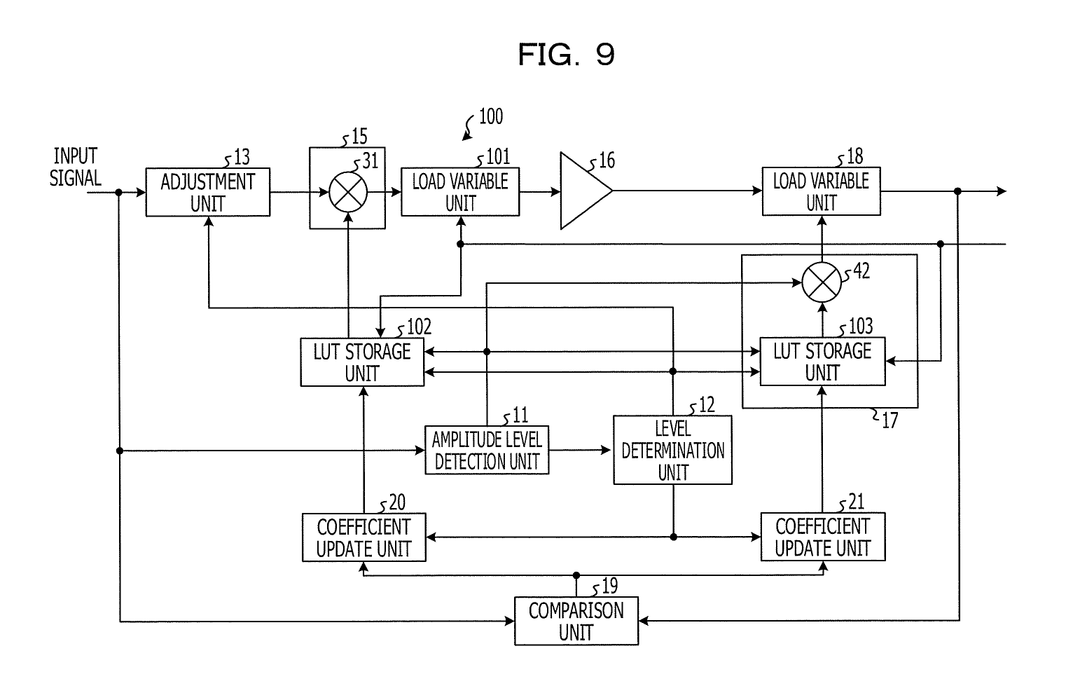

FIG. 9 is a block diagram illustrating an example of an amplification device according to the second embodiment. In FIG. 9, the amplification device 100 includes a load variable section 101, and the LUT storage sections 102 and 103.

The load variable section 101 is provided at the input of the amplifier 16. The load variable section 101 shifts the frequency of a signal that is input to the amplifier 16, to a frequency that is indicated by frequency band setting information, by changing the load based on the frequency band setting information.

For example, when the amplification device 100 is applied to a communication device that is allowed to perform communication in one of a plurality of frequency bands, the frequency band that is used for the communication is instructed to the load variable section 101 based on the frequency band setting information. The load variable section 101 shifts the frequency of the signal that is input to the amplifier 16, to the frequency that is indicated by the frequency band setting information. As a result, the frequency of the transmission signal is adjusted to a frequency in the frequency band that is used for the communication. That is, variable tuning is performed over a certain band, so that multiband communication may be performed. In order to achieve the multiband communication, a certain offset voltage is applied to the load variable section 101 to determine a band, and a wide band signal that causes load impedance to move at high speed in accordance with an envelope is added to the offset voltage.

When the frequency band to be used is changed, distortion characteristics are also changed. Therefore, the LUT storage sections 102 and 103 include a plurality of look-up tables that respectively correspond to a plurality of frequency bands. The LUT storage sections 102 and 103 perform switching into a look-up table that corresponds to a frequency band that is indicated by the input frequency band setting information, and operate using the switched look-up table, similarly to the LUT storage sections 14 and 41 that are described in the first embodiment. Here, the configuration is described above in which the LUT storage sections 102 and 103 hold the plurality of look-up tables, and switching of the look-up table is performed in accordance with the frequency band setting information, but the embodiment is not limited to such a configuration. For example, a configuration may be employed in which data to be held in a look-up table that corresponds to the frequency band to be used is input from a control section (not illustrated) to the LUT storage sections 102 and 103, and the LUT storage sections 102 and 103 update the look-up table using such data.

As described above, according to the second embodiment, in the amplification device 100, since the load variable section 101 is provided at the input of the amplifier 16 and changes the load based on the frequency band setting information, the frequency of the signal that is adjusted by the adjustment section 13 is changed.

In such a configuration of the amplification device 100, the amplification device that is allowed to be applied to a communication device that performs multiband communication may be achieved.

### Another Embodiment

[1]

In the first embodiment and the second embodiment, the scheme is described in which the mode is switched in accordance with an amplitude value, but the embodiments are not limited to such a scheme. For example, a scheme may be employed in which the amplitude of the signal that is input to the amplifier is adjusted at a certain level regardless of an amplitude value. That is, for example, there is a communication scheme in which the input level of an amplifier is kept unchanged, and power supply voltage of the amplifier is varied in response to an amplitude level. To such a scheme, the processing in the high level mode that is described in the first embodiment and the second embodiment may be applied.

[2]

The amplification devices according to the first embodiment and the second embodiment may be achieved, for example, by the following hardware configuration.

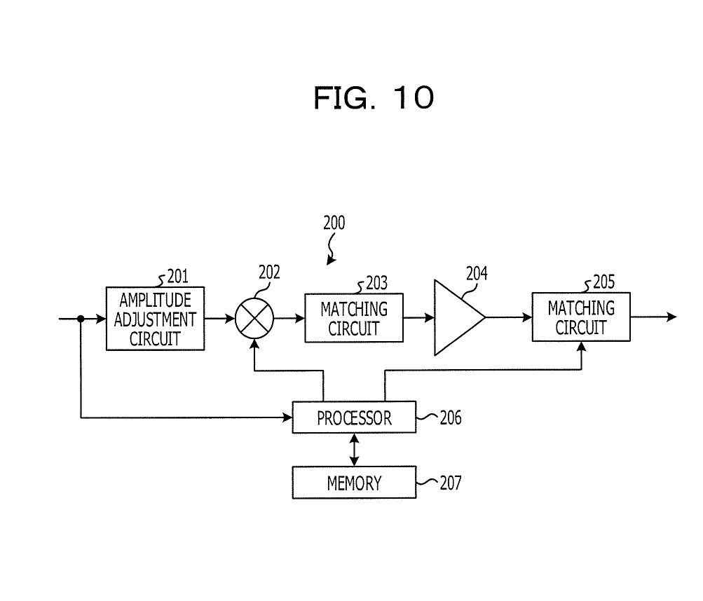

FIG. 10 is a diagram illustrating a hardware configuration example of the amplification device. In FIG. 10, an amplification device 200 includes an amplitude adjustment circuit 201, a multiplier 202, a matching circuit 203, an amplifier 204, a matching circuit 205, a processor 206, and a memory 207. The amplitude adjustment circuit 201, the multiplier 202, the matching circuit 203, the amplifier 204, and the matching circuit 205 respectively correspond to the adjustment section 13, the multiplier 31, the load variable section 101, the amplifier 16, and the load variable section 18 in the amplification devices according to the first embodiment and the second embodiment.

As an example of the processor 206, a central processing unit (CPU), a digital signal processor (DSP), a field programmable gate array (FPGA), or the like is employed. In addition, as an example of the memory 207, a random access memory (RAM) such as a synchronous dynamic random access memory (SDRAM), a read only memory (ROM), a flash memory, or the like is employed.

In addition, various processing functions that are executed in the amplification devices according to the first embodiment and the second embodiment may be achieved by causing a processor that is included in the amplification device to execute a program that is stored in a memory such as a non-volatile storage medium. That is, programs that correspond to the processes that are executed by the amplitude level detection section 11, the level determination section 12, the comparison section 19, the coefficient update sections 20 and 21, and the LUT storage sections 14, 41, 102, and 103 may be recorded to the memory 207, and each of the programs may be executed by the processor 206. In addition, the holding function by the LUT storage sections 14, 41, 102, and 103 may be achieved by the memory 207.

The above-described hardware configuration is merely an example, and the embodiments are not limited to such a configuration. For example, all of the processes of the function sections that are described in the first embodiment and the second embodiment may be achieved by the processor.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An amplification device comprising:
an amplitude adjustment circuit configured to adjust an amplitude level of an input signal so as to keep the amplitude level within a given range;
an amplifier configured to amplify the adjusted signal; and
a circuitry configured to change an amplitude level of the amplified signal, based on the amplitude level of the input signal and a first distortion compensation corresponding to the amplitude level of the input signal.

2. The amplification device according to claim 1, wherein
the circuitry includes:
a processor configured to generate a control signal based on the amplitude level of the input signal and the first distortion compensation; and
a first matching circuit, arranged at an output of the amplifier, and configured to change a load of the first matching circuit using the control signal for changing the amplitude level of the amplified signal.

3. The amplification device according to claim 2, wherein
the processor is configured to detect the amplitude level of the input signal.

4. The amplification device according to claim 2, wherein
the processor is configured to generate the control signal by correcting a signal indicating the amplitude level of the input signal based on a first distortion compensation coefficient for the first distortion compensation.

5. The amplification device according to claim 4, further comprising:
a memory configured to store at least one first table that associates each of a first group of amplitude levels with each of a plurality of first distortion compensation coefficients, wherein
the processor is configured to generate the control signal by multiplying the signal indicating the amplitude level of the input signal by the first distortion compensation coefficient that is among the plurality of first distortion compensation coefficients and is associated with the amplitude level of the input signal in the at least one first table.

6. The amplification device according to claim 5, wherein
the memory is further configured to store at least one second table that associates each of a second group of amplitude levels with each of a plurality of second distortion compensation coefficients,
the processor is further configured to multiply the adjusted signal by a second distortion compensation coefficient that is among the plurality of second distortion compensation coefficients and is associated with the amplitude level of the input signal in the at least one second table, and
the amplifier is configured to amplify the multiplied adjusted signal.

7. The amplification device according to claim 6, wherein
the input signal includes an amplitude component and a phase component,
the first distortion compensation coefficient includes an amplitude component coefficient,
the amplitude component coefficient of the first distortion compensation coefficient is kept unchanged when the amplitude level of the input signal is less than a threshold,
the second distortion compensation coefficient includes a phase component coefficient and an amplitude component coefficient, and
the amplitude component coefficient of the second distortion compensation coefficient is kept unchanged when the amplitude level of the input signal is at the threshold or greater than the threshold.

8. The amplification device according to claim 6, wherein
the memory is configured to store a plurality of first tables that respectively correspond to a plurality of frequency bands, and a plurality of second tables that respectively correspond to the plurality of frequency bands,
the processor is configured to:
correct the amplitude level of the input signal using the first distortion compensation coefficient that corresponds to an indicated frequency band by information relating to the input signal and is stored in the at least one first table, and
multiply the adjusted signal by the second distortion compensation coefficient that corresponds to the indicated frequency band and is stored in the at least one second table.

9. The amplification device according to claim 1, wherein
the amplitude adjustment circuit is configured to:
output the adjusted signal when the amplitude level of the input signal is at a threshold or greater than the threshold, and
output the input signal without adjusting the amplitude level of the input signal when the amplitude level of the input signal is less than the threshold, and
the amplifier is configured to amplify the output signal from the amplitude adjustment circuit.

10. The amplification device according to claim 1, wherein
the circuitry includes a second matching circuit, arranged between the amplitude adjustment circuit and the amplifier, and configured to change a load of the second matching circuit.

11. The amplification device according to claim 10, wherein
the second matching circuit is configured to change a frequency of the adjusted signal by changing the load of the second matching circuit based on an indicated frequency band by information relating to the input signal, and
the amplifier is configured to amplify the changed adjusted signal.

12. The amplification device according to claim 2, wherein
the input signal includes an amplitude component and a phase component, and
the processor is configured to:
perform the first distortion compensation for the amplitude component by superimposing amplitude information of the amplitude component on the amplified signal at an output of the amplifier, and
perform a second distortion compensation for the phase component on the adjusted signal at an input of the amplifier.

13. The amplification device according to claim 1, wherein
the given range is set based on at least one of an efficiency of the amplifier, a saturation state for an output of the amplifier, and a characteristic for an excessive input of the amplifier.

14. The amplification device according to claim 1, wherein
the input signal includes an amplitude component and a phase component, and
the amplitude adjustment circuit is configured to adjust the amplitude level of the input signal so as to remove amplitude information of the amplitude component.

15. The amplification device according to claim 14, wherein
the circuitry is configured to change the amplitude level of the amplified signal so as to restore the removed amplitude information with the first distortion compensation.

16. The amplification device according to claim 9, wherein
the threshold is set based on at least one of an efficiency of the amplification device, and a characteristic of the circuitry for changing the amplitude level of the amplified signal.

17. An amplification method comprising:
adjusting an amplitude level of the input signal so as to keep an amplitude level of an input signal within a given range, the input signal including an amplitude component and a phase component;
amplifying, by an amplifier, the adjusted signal;
performing, by a processor, a first distortion compensation for the amplitude component by superimposing amplitude information of the amplitude component on the amplified signal at an output of the amplifier; and
performing a second distortion compensation for the phase component on the adjusted signal at an input of the amplifier.

18. The amplification method according to claim 17, further comprising:
changing the amplitude level of the amplified signal, based on the amplitude level of the input signal and the first distortion compensation corresponding to the amplitude level of the input signal.

19. A transmission device comprising:
an amplitude adjustment circuit configured to adjust an amplitude level of a transmission signal so as to keep the amplitude level within a given range;
an amplifier configured to amplify the adjusted signal;
a circuitry configured to change an amplitude level of the amplified signal, based on the amplitude level of the transmission signal and a first distortion compensation corresponding to the amplitude level of the transmission signal; and
a transmitter configured to transmit the amplified signal.
